(19) United States
(12) Patent Application Publication
(10) Pub. No.: US 2014/0055958 A1
(43) Pub. Date: Feb. 27, 2014

(54) 3D TOUCH MODULE AND ITS METHODE OF MANUFACTURING

(71) Applicants: Li-Te HSU, Taipei City (TW); Lin-Yeh YANG, Taipei City (TW)

(72) Inventors: Li-Te HSU, Taipei City (TW); Lin-Yeh YANG, Taipei City (TW)

(21) Appl. No.: 13/592,535

(22) Filed: Aug. 23, 2012

(51) Int. Cl. H05K 7/00; B32B 37/14; B32B 38/00; B82Y 99/00; B82Y 30/00

(52) U.S. Cl. 361/728; 156/221; 977/742; 977/952

(57) ABSTRACT

A 3 dimensional touch module of the present invention including: a base plate protruding outwards, an adhesive layer on the base plate, an induction thin film fixed on the base plate by means of the adhesive layer and a substrate layer combined with the induction thin film by a mode of injection shaping. The method of manufacturing mainly has the base integrally press shaped after being stuck firm with each other to form a protruding shape, this can not only provide a feeling of 3 dimensional touching, but also can simplify the process of manufacturing.

### BACKGROUND OF THE INVENTION

1. Field of the Invention

The present invention is related to a touch module and a method of manufacturing of it; and especially to a stereo (3 dimensional) touch module used on a touch panel, and a method of manufacturing of the touch module.

2. Description of the Prior Art

In the recent years, touch panels gradually took the place of conventional stereo push-button type key boards, and are widely used on mobile phones, digital cameras and tablet computers, and also applied to many control panels of electric appliances. And by progressing of the techniques on touch panels day by day, sensitivity of touch panels gets increased a lot; plus application of multiple dots touch control, touch panels become more convenient for use, needing of touch panels on the markets is sustainingly increasing.

The known touch panels now mostly are designed as planar on their appearances, such as is shown in FIG. 1, when a planar touch panel 100 is provided on a mobile phone 200, it limits the modeling on the appearance of the mobile phone 200; this renders the products of various manufacturers quite identical, there is no innovation and is lack of freshness; when in operation of touch control, a user only has the feeling of planar touching no matter he touch controlling any area on such a touch panel, and feels monotonic and non interesting.

In related prior techniques, a USA publication US20100103138A1 (TWI360073) provided the manufacturing method and structure of a curved electrical capacity type touch panel, the technical characteristic thereof is to heating plasticize a soft inductive thin film with a shaping pressure die to form a cubic curved shape, then the soft inductive thin film is stuck on an inwardly bending curved surface of a base plate likewise in a cubic curved shape by taking a ticking mode, and can be assembled after sticking to form a touch panel with a curved surface.

The above prior techniques surely provided an advanced technique to get a touch panel different from the conventional planar touch panels to increase the fun of using; however, it still has quite a lot of defects wanted to be improved in its practice of manufacturing, for example:

1. The soft inductive thin film and the base plate must be processed to separately form a cubic curved shape each during the process of manufacturing, and then are stuck with each other to form the touch panel; such process of manufacturing is quite complicated.

2. In the structure of the produced article of touch panel, the soft inductive thin film is exposed and uncovered above the inwardly bending curved surface; it is subjected to impacting and damage when it is in the process of piling up in a warehouse or in the process of conveying after being manufactured.

3. By virtue that in using the touch panel, it still must be assembled in an electronic product such as a mobile phone, while the above mentioned article of touch panel is not given a technique for it to be combined with the produced article of touch panel.

### SUMMARY OF THE INVENTION

Therefore, the object of the present invention is to provide a structurally brand new 3 dimensional touch module which is stereo by touching and is fun for use, as well as the method of manufacturing of the touch module; it not only is simple in its process of manufacturing, but also has much higher value of usage.

Thereby, the 3 dimensional touch module of the present invention includes: a base plate, an adhesive layer, an induction thin film and a substrate layer, the base plate includes a touch surface protruding outwards, and a base surface which is on an opposite side to the touch surface and protrudes to an identical direction as the touch surface does, the adhesive layer is on the base surface, the induction thin film is fixed on a surface of the adhesive layer, which surface is far away from the base plate, and the induction thin film is integrally press shaped with the base plate and is stuck to the base plate in matching the contour of the latter by means of the adhesive layer, the substrate layer is combined with the surface of the induction thin film by a mode of injection shaping.

The method of manufacturing of the 3 dimensional touch module of the present invention includes:

step A: to provide a planar base plate which includes a touch surface and a base surface respectively on mutually opposite sides;

step B: to stick an induction thin film on the base surface of the base plate by means of an adhesive layer;

step C: to heat the base plate and the induction thin film and to integrally pressing shape the base plate on the induction thin film to form a protruding shape;

step D: to form a substrate layer on the surface of the induction thin film by a mode of injection shaping.

As compared to the prior art, the present invention can provide the feeling of 3 dimensional touching by way of making the base plate protrude outwards, and further can increase fun of using. The induction thin film can be flexible, it is fixed on the base plate and then is press shaped and integrally formed together with the base plate, the induction thin film thus is stuck to the base plate in coincident in contour with the latter; this not only endues the induction thin film with good inductive sensitivity, but also can simplify the process of manufacturing. And more, the substrate layer combining by the mode of injection shaping on the surface of the induction thin film can prevent the induction thin film from touching by the outside things and thereby provides a function of protection.

The present invention will be apparent in the above mentioned and other technical content, features and function after reading the detailed description of the four preferred embodiments thereof in reference to the accompanying drawings. It should be noted that in the following description, similar elements are marked with same numbers.

### BRIEF DESCRIPTION OF THE DRAWINGS

FIG. 1 is a perspective view showing the appearance of a conventional electronic product provided with a planar touch panel;

FIG. 2 is a perspective view showing the appearance of an electronic product of a 3 dimensional touch module of the present invention;

FIG. 3 is a sectional view showing a first preferred embodiment of the electronic product of the 3 dimensional touch module of the present invention;

FIG. 4 is a flow chart block diagram showing a first preferred embodiment of the method of manufacturing the 3 dimensional touch module of the present invention;

FIG. 5 is a schematic flow chart showing the steps of a method of manufacturing of the present invention;

FIG. 6 is a perspective view showing another appearance of the electronic product provided with the 3 dimensional touch module of the present invention;

FIG. 7 is a sectional side view taken from FIG. 6 showing the relationship of combining of the first preferred embodiment of the electronic product of the 3 dimensional touch module of the present invention with the electronic product;

FIG. 8 is a sectional view showing a second preferred embodiment of the electronic product of the 3 dimensional touch module of the present invention;

FIG. 9 is a sectional view showing a third preferred embodiment of the 3 dimensional touch module of the present invention provided with an electronic product with another appearance;

FIG. 10 is a sectional view showing the third preferred embodiment of the 3 dimensional touch module of the present invention;

FIG. 11 is a sectional view taken from FIG. 9 showing the relationship of combining of the third preferred embodiment of present invention with the electronic product;

FIG. 12 is a sectional view showing a fourth preferred embodiment of the 3 dimensional touch module of the present invention.

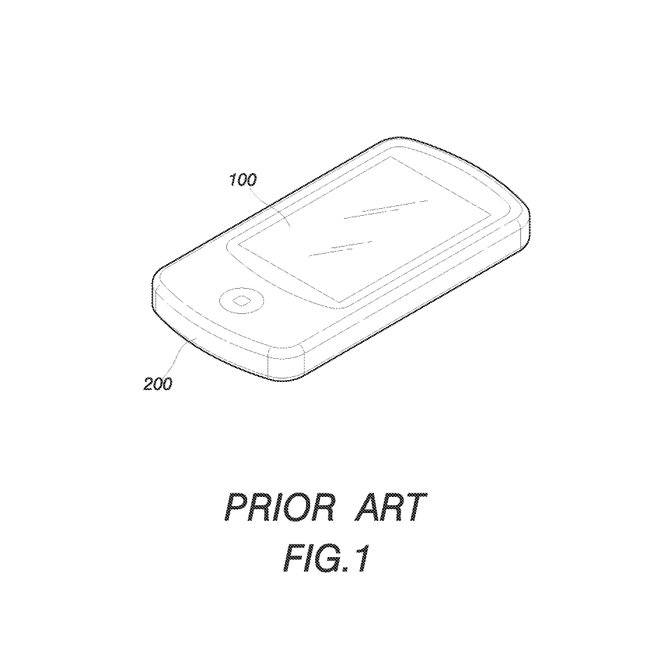

### DETAILED DESCRIPTION OF THE PREFERRED EMBODIMENT

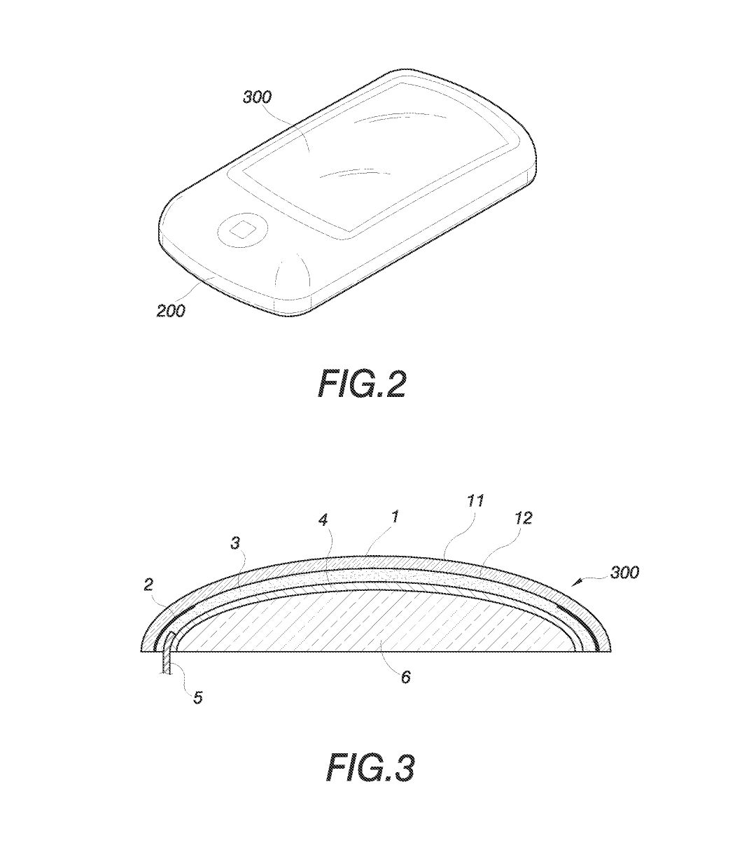

Referring to FIG. 2, a 3 dimensional touch module 300 of the present invention can be provided on an electronic product 200 such as a mobile phone, the touch module 300 has its left and the right sides of and/or its front and the rear sides protruded in an arched way gradually from the sides to its center area; for example, except its left and right sides, the 3 dimensional touch module 300 in the drawings also has its front and the rear sides protruded in an arched way gradually from the sides to its center area.

As shown in FIGS. 2, 3, the first preferred embodiment of the 3 dimensional touch module 300 includes: a base plate 1, a printed layer 2, an adhesive layer 3, an induction thin film 4, a soft circuit board 5 and a substrate layer 6.

The base plate 1 can be made a thin film shape of transparent material, such material for example can be polyethylene terephthalate (PET), the material of the base plate 1 is not limited, so long it is transparent, and is able to be plasticized after being heated; the base plate 1 includes a protruding touch surface 11 which protrudes outwards, and a base surface 12 which is on a opposite side to the touch surface 11 and protrudes to an identical direction as the touch surface 11 does. Wherein the touch surface 11 faces to an outer side (namely faces to a user). The base plate 1 of this embodiment is non planar; particularly, the base plate 1 protrudes outwards in an arched way gradually from the left and the right sides of it toward its center area, thereby the touch surface 11 and the base surface 12 are both protrudes outwards in an arched way, the center area thereof is in an arc shape.

The printed layer 2 is provided on the base surface 12 of the base plate 1 and is located between the base plate 1 and the adhesive layer 3, and it is formed by being printed with ink and dried. By virtue that the present invention still needs in application to use an engaging structure (which is not shown) to be fixed to a lower housing also not shown, the printed layer 2 thus is provided which has thereon patterns or letters able to obstruct the engaging structure and other assembling elements undesired to be seen in the module, thereby an effect of getting a good appearance can be obtained. However, the printed layer 2 is not a necessary element designed for the present invention, nor is the key point of improvement of the present invention; thereby no further description should be given hereinafter.

The material of the adhesive layer 3 is optical clear adhesive (OCA adhesive), it is located on the base surface 12 and is used on the base plate 1, in order that the induction thin film 4 and the soft circuit board 5 can be fixed to each other.

The induction thin film 4 is stuck on a surface of the adhesive layer 3, which surface is far away from the base plate 1, in particular, it is firmly stuck on the bottom surface of the adhesive layer 3, and the base plate 1 shall be formed between itself and a touching thing (e.g. a finger of a user or some other touching article) a variation in capacitor value to generate induction when it is touched by the touching thing, and then a touch signal is created, the induction thin film 4 can be a transparent electric conductive thin film, for instance: a nanometer carbon tube thin film or some other similar thin film with similar nature, the nanometer carbon tube thin film mentioned has the advantages including good electric conductivity, high temperature proof, high stretching strength, high structure strength, light transparency and easiness for manufacturing etc., hence it is suitable for being used as a transparent electric conductive thin film in a touch module. Particularly, the induction thin film 4 can only include a layer of nanometer carbon tube thin film or can be stuck on a induction base film (not shown) by using an OCA adhesive nanometer carbon tube thin film; the induction base film (such as a PET thin film) thereby constitutes a tri-layer film structure including a base film, a kind of adhesive and a induction base film. However, in practicing the present invention, there is no need to limit the form and number of films of the induction thin film 4.

The soft circuit board 5 is located between the base plate 1 and the induction thin film 4, and is stuck firm by means of the adhesive layer 3.

The substrate layer 6 is made of transparent resin, for instance: polycarbonate (PC). The substrate layer 6 is a supporting structure for film layers above it, to be used as a support for a main control area against pressing during touch control, meanwhile it can protect the induction thin film 4; especially when the 3 dimensional touch module 300 of the present invention is mounted on an electronic product such as a mobile phone, it can protect an display main body (LCD) to avoid the display main body from touching the induction thin film 4, thus chance of damage in using the induction thin film 4 or the display main body is reduced.

The present invention mainly is to make the base plate 1 a non planar design, in order that the appearance of the touch module becomes stereo which is different from general planar touch module; when in use for touch control, a new and special touch operation is provided. One thing is worth mentioning, as compared of the 3 dimensional touch module 300 of the present invention with a prior planar touch panel, under the condition that they have same width, the present invention can provide a larger touch controlling area. And more, the induction thin film 4 is stuck to the base plate 1 in matching the contour of the latter by using the adhesive layer 3, thereby, in addition to provide the feeling of 3 dimensional touching, the present invention still has a fine effect of touch sensitivity.

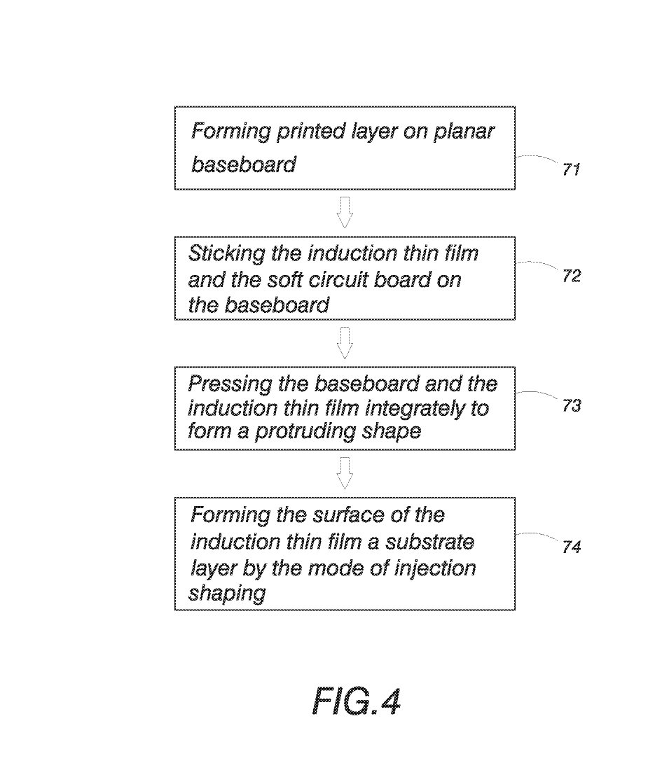

Referring to FIGS. 3 to 5, a first preferred embodiment of the method of manufacturing of the 3 dimensional touch module of the present invention includes:

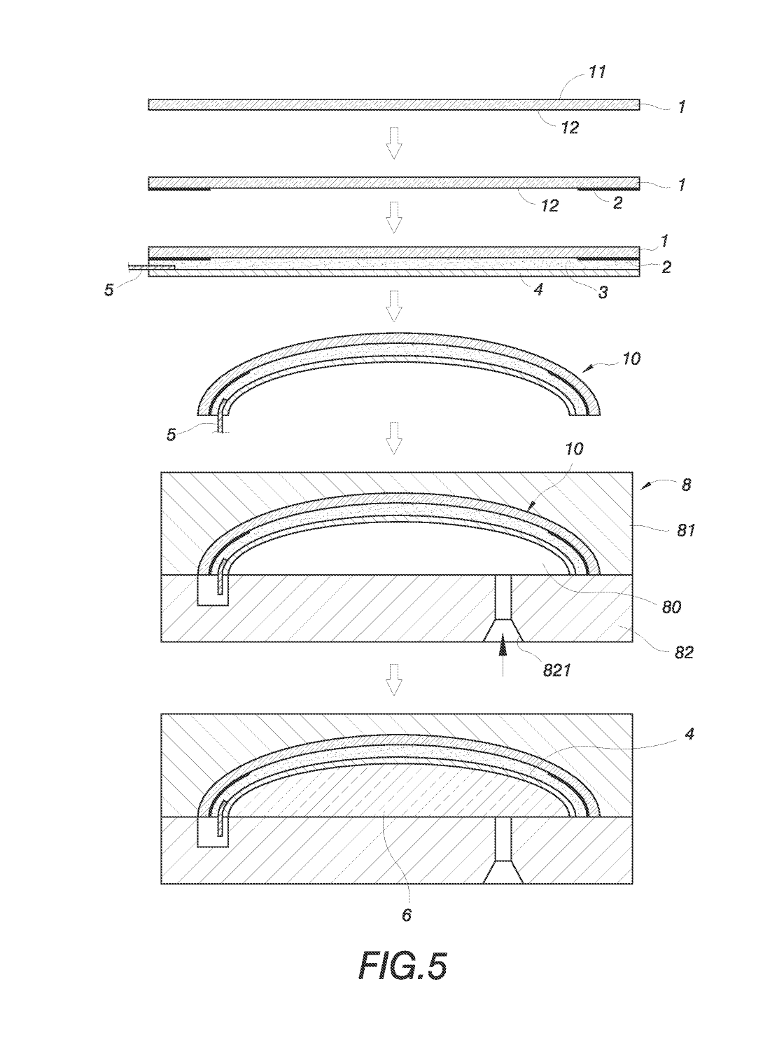

(1) proceeding to step 71, in manufacturing the base plate 1 initially of the present invention, the base plate 1 is not yet processed to be a curved shape, rather it is planar (as shown in FIG. 5); in the first place, a mode of silk-screen printing is used to print ink on the base surface 12 of the base plate 1, then the base plate 1 is dried to form the printed layer 2, the way of drying can be done by baking;

(2) proceeding to step 72, an adhesive is applied on the base surface 12 of the base plate 1, then a soft circuit board 5 and induction thin film 4 are placed on the base plate 1 with the adhesive sandwiching between them, and the adhesive layer 3 is formed after being dried of the adhesive; in this way, the soft circuit board 5 and induction thin film 4 can be fixed together by the adhesive layer 3;

(3) proceeding to step 73, the semi-finished article in the step 72 is heated, and the base plate 1 and the induction thin film 4 are appropriately softened to be convenient for plasticization, further a high pressure machine (not shown) and a copper film (not shown) are use to pressing manufacturing the film layers including the base plate 1 and the induction thin film 4 etc. to be integrally formed a stereo semi-finished article 10 protruding outwards, the base plate 1 and the induction thin film 4 thus are formed their outward protruding types. It needs to clearly explain that the completely shaped stereo semi-finished article 10 has at its left and right sides some waste material which can be removed by a cutting step, while preferably, before pressing manufacturing, the entire semi-finished article can be stuck on its two mutually opposite sides each with a protecting layer in order that the stereo semi-finished article 10 is protected;

(4) proceeding to step 74, the stereo semi-finished article 10 is placed into a mould unit 8 having a predetermined shape, the mould unit 8 includes: an upper die 81 and a lower die 82 having a pouring mouth 821, the lower die 82 and the upper die 81 formed a die cavity 80 provided for placing the stereo semi-finished article 10, then in the mould unit 8 an injection molding way is taken to form the substrate layer 6, this step has a kind of molten plastic material poured into the pouring mouth 821, and the mould is opened after the material is dried, and the plastic material is solidified to form the substrate layer 6 which is integrally combined beneath the induction thin film 4, and manufacturing is completed.

One thing is worth mentioning, the induction thin film 4 of the present invention adopts a nanometer carbon tube thin film which can be directly made a thin sheet shape and thus is flexible, thereby it can be adhered and fixed with the soft circuit board 5 by using the adhesive layer 3, and an adhering step taken once only can make them fixed simultaneously, this is quite convenient; sometimes, by virtue that the nanometer carbon tube thin film is high temperature proof, the temperature in the pressing manufacturing step is not damageable against the nanometer carbon tube thin film; further by the fact that the nanometer carbon tube thin film can be plasticized at will, it is suitable for the process of pressing manufacturing of the present invention. On the other hand, the touch modules sold in the markets generally use the material indium tin oxide (ITO) as induction thin films, while by the fact that ITO must be formed by the way of vacuum film plating, and its structure is rigid and is not ductile or bendable (unable for ducting or bending); therefore, the ITO thin films are not applicable to the manufacturing process of the present invention.

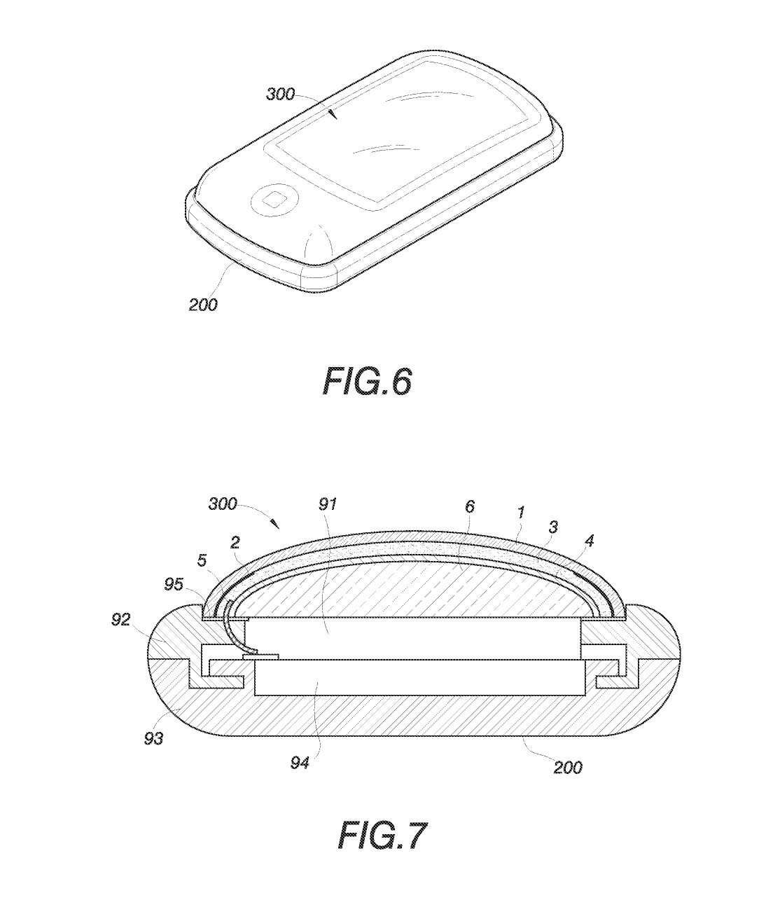

Referring to FIGS. 6, 7, in application, the 3 dimensional touch module 300 of the present invention can be installed as a whole on an display main body 91 (such as an LCD panel) of an electronic product 200 on a mobile phone or a camera etc., the electronic product 200 includes, in addition to the display main body 91, an upper housing 92, a lower housing 93 and a printed circuit board 94 located beneath the display main body 91 as well as electrically connected with the soft circuit board 5, when in assembling, the module of the present invention and the upper housing 92 of the electronic product 200 are stuck and fixed together by using a two-side adhesive tape 95, if it is required by appearance that the size of the viewing window shall be near that of the peripheral size of an equipment, an engaging structure between the upper housing 92 and the lower housing 93 can be obstructed by the printed layer 2, the engaging structure will not be seen if one observe from above the entire module, beauty of the zoned to be viewed of the panel thus can be kept.

And more, as stated above, when the 3 dimensional touch module 300 of the present invention is installed on the electronic product 200, the substrate layer 6 is located between the induction thin film 4 and the display main body 91 and can protect the display main body 91 and the induction thin film 4 for preventing them from contacting with each other, thereby the chance of damaging them is reduced.

In conclusion of the above, a sense of 3 dimensions can be obtained by protruding of the base plate 1, and this can create a feeling of novelty and can increase fun of using. Further the induction thin film 4 is stuck and fixed together with the base plate 1 in matching the contour of the latter by using the adhesive layer 3, and then is integrally press shaped with the base plate 1, thus the process of manufacturing can be simplified, and the induction thin film 4 can be endued with good inductive sensitivity.

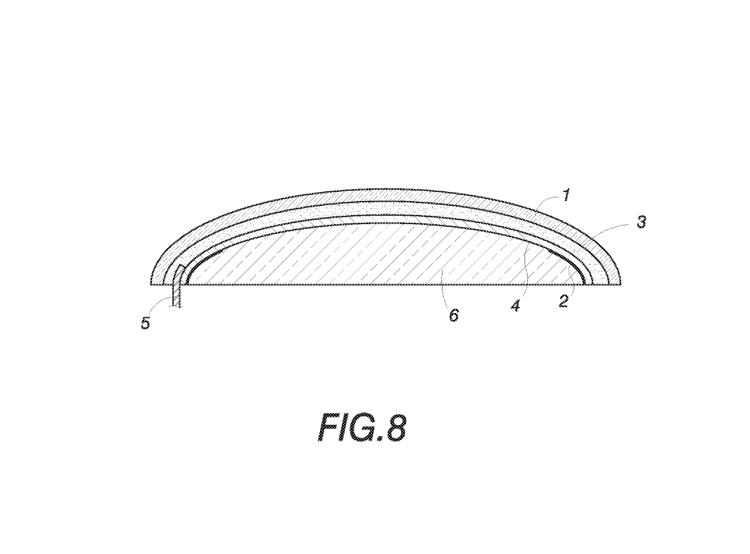

Referring to FIG. 8, a second preferred embodiment of the 3 dimensional touch module of the present invention is generally same as the first preferred embodiment, it is different from the first preferred embodiment in that: the printed layer 2 is provided on the surface of the induction thin film 4, and is located between the induction thin film 4 and the substrate layer 6. When in manufacturing of the second preferred embodiment, the induction thin film 4 is in the first place stuck on the base plate 1, and then the printed layer 2 is printed in the mode of screen printing, after that, the above mentioned manufacturing process of pressing shaping for making a curved shape is proceeded to. By virtue that the effect of the second preferred embodiment is same as that of the first preferred embodiment, not further narration is necessary.

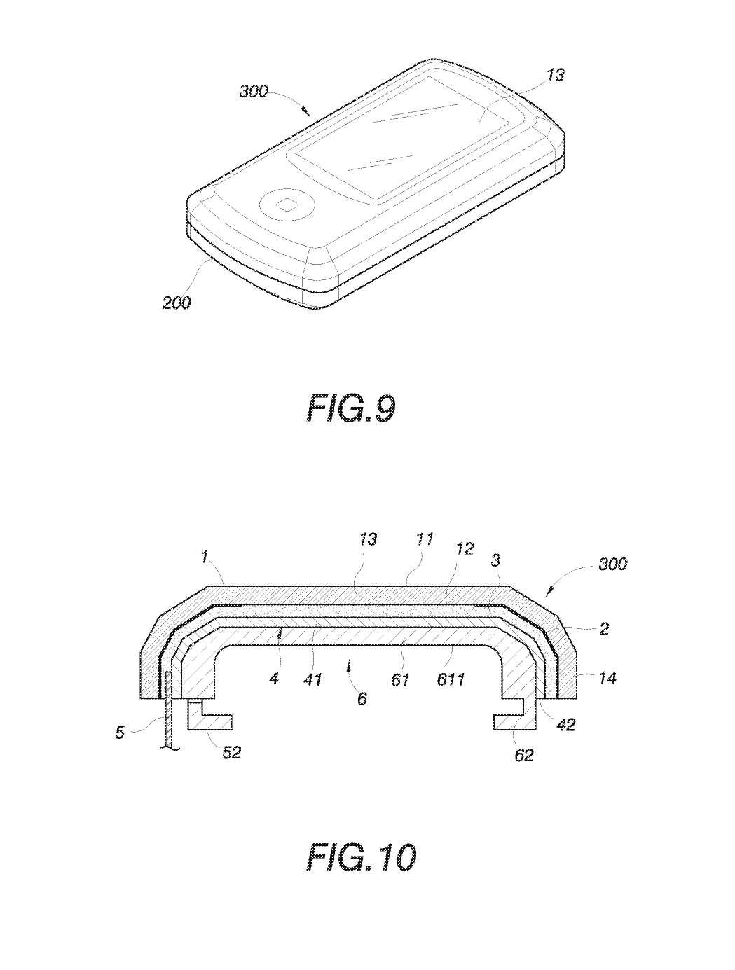

Referring to FIGS. 9 and 10, a third preferred embodiment of the 3 dimensional touch module of the present invention is generally same as the first preferred embodiment, it is different from the first preferred embodiment in that: the stereo type of the touch module of this embodiment is different from that of the first preferred embodiment. In this third preferred embodiment, the base plate 1 also protrudes outwards, a middle area of the base plate 1 is planar; the base plate 1 includes a displaying zone 13 and two connecting zones 14 respectively connected with the left and right lateral sides of the displaying zone 13; the area between the connecting zones 14 and the displaying zone 13 is a non-linear connecting area.

A substrate layer 6 of the third preferred embodiment includes a reversed U shaped main layer 61, and an engaging member 62 protruding out of the main layer 61 and corresponding by position with the printed layer 2. In which a bottom surface 611 of the main layer 61 is non planar, while the main layer 61 is extended in corresponding with the contour of the outwardly protruding shape of the base plate 1.

The induction thin film 4 has a first induction zone 41 in corresponding by contour with the displaying zone 13 of the base plate 1 and adhered to the latter, and has two second induction zones 42 in corresponding by contour with the connecting zones 14 of the base plate 1 respectively to connect with the left and right lateral sides of the first induction zone 41 and adhered to the connecting zones 14.

The process of manufacturing of this third preferred embodiment is same as that of the first preferred embodiment, but when the shape of the 3 dimensional module is press shaped in the embodiment, a die which matches with the protruding modeling of the embodiment must be chosen for use; and certainly, the subsequent manufacturing of the substrate layer 6 by using the mode of in-mold injection shaping, also a die which has appropriate die cavity shape must be chosen for use too. By the fact that the process of manufacturing and the effect achieved of the embodiment are both same as that of the first preferred embodiment, no description is needed hereafter.

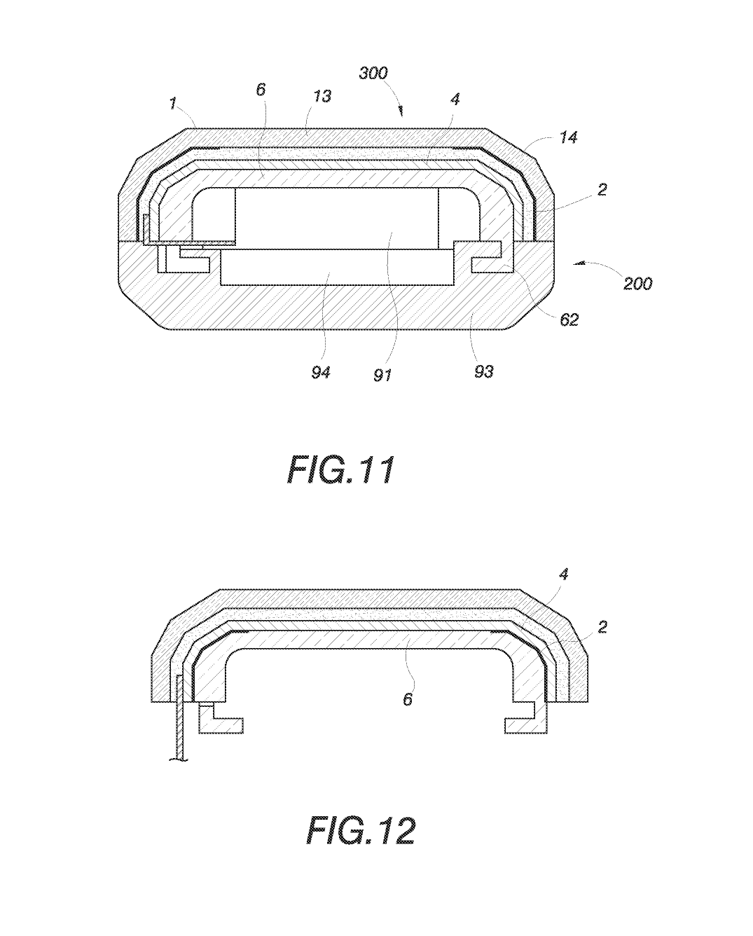

Referring to FIG. 11, in application, the present invention can be installed as a whole on a display main body 91 (such as an LCD panel) of the electronic product 200 of a mobile phone or a camera etc., the electronic product 200 further includes a lower housing 93 and a printed circuit board 94. A displaying zone 13 of the base plate 1 and the substrate layer 6 both of the embodiment in corresponding by position with the displaying zone 13 is a viewing window; and connecting zones 14 of the base plate 1 are respectively in corresponding by position with the two second induction zones 42 and is equal to an upper housing of the electronic product 200, when in assembling of this embodiment with the electronic product 200, they can be fixed so long the engaging member 62 of the substrate layer 6 is engaged with the engaging structure of the lower housing 93 of the electronic product 200.

Thereby the 3 dimensional touch module of the present invention is formed to simultaneously have a display main body having the touch controlling function (corresponding to the displaying zone 13 of the base plate 1) and a surrounding housing (corresponding to the connecting zones 14 of the base plate 1), that is to say, the touch module can be divided by function into a display block and a housing block, the display block and the housing block are both covered by the induction thin film 4, hence the two blocks both can be contacted to thereby provide a larger touch area.

Referring to FIG. 12, a fourth preferred embodiment of the 3 dimensional touch module of the present invention is generally same as that of the third preferred embodiment, it is different from the third preferred embodiment in that: the printed layer 2 of the third preferred embodiment is located on the surface of the induction thin film 4, and is located between the induction thin film 4 and the substrate layer 6.

The embodiments stated above are only for illustrating the present invention, and not for giving any limitation to the scope of the present invention. It will be apparent to those skilled in this art that various equivalent modification or changes without departing from the spirit of this invention shall also fall within the scope of the appended claims.

1. A 3 dimensional touch module comprising:
a base plate including: a protruding touch surface which protrudes outwards, and a base surface which is on a opposite side to said touch surface and protrudes to an identical direction as said touch surface does;
an adhesive layer located on said base surface;
an induction thin film stuck on a surface of said adhesive layer, said surface is far away from said base plate, said induction thin film is press shaped with said base plate and is stuck to said base plate in matching a contour of said base plate by means of said adhesive layer; and
a substrate layer combined with said surface of said induction thin film by a mode of injection shaping.

2. The 3 dimensional touch module as claimed in claim 1, wherein said induction thin film is a nanometer carbon tube thin film.

3. The 3 dimensional touch module as claimed in claim 1, wherein said base plate of said touch module has its left and the right sides of and/or its front and the rear sides protruded in an arched way gradually from the sides to a center area of said base plate.

4. The 3 dimensional touch module as claimed in claim 1, wherein a middle area of said base plate is planar or curved.

5. The 3 dimensional touch module as claimed in claim 1, wherein said base plate includes a displaying zone and two connecting zones respectively connected with a left and a right lateral side of said displaying zone; said area between said connecting zones and said displaying zone is a non-linear connecting area, said induction thin film has a first induction zone in corresponding by contour with and adhered to said displaying zone, and has two second induction zones in corresponding by contour with said connecting zones respectively to connect with a left and a right lateral side of said first induction zone and adhered to said connecting zones.

6. The 3 dimensional touch module as claimed in claim 1, wherein said touch module further comprises a soft circuit board located between said base plate and said induction thin film, and is stuck firm by means of said adhesive layer.

7. The 3 dimensional touch module as claimed in claim 1, wherein said touch module further comprises a printed layer provided on said base surface of said base plate and is located between said base plate and said adhesive layer.

8. The 3 dimensional touch module as claimed in claim 1, wherein said touch module further comprises a printed layer provided on said induction thin film and is located between said induction thin film and said substrate layer.

9. The 3 dimensional touch module as claimed in claim 1, wherein said substrate layer includes a main layer, and at least an engaging member protruding out of said main layer.

10. A 3 dimensional touch module comprising:
a base plate having its left and the right sides of and/or its front and the rear sides protruded in an arched way gradually from the sides to its center area; said base plate including a protruding touch surface which protrudes outwards, and a base surface which is on a opposite side to said touch surface and protrudes to an identical direction as said touch surface does;
an adhesive layer located on said base surface;
an induction thin film made from a nanometer carbon tube thin film and stuck on a surface of said adhesive layer, said surface is far away from said base plate, said induction thin film is press shaped with said base plate and is stuck to said base plate in matching a contour of said base plate by means of said adhesive layer; and
a substrate layer combined with said surface of said induction thin film by a mode of injection shaping.

11. The 3 dimensional touch module as claimed in claim 10, wherein a middle area of said base plate is planar or curved.

12. The 3 dimensional touch module as claimed in claim 10, wherein said base plate includes a displaying zone and two connecting zones respectively connected with a left and a right lateral side of said displaying zone; said area between said connecting zones and said displaying zone is a non-linear connecting area, said induction thin film has a first induction zone in corresponding by contour with and adhered to said displaying zone, and has two second induction zones in corresponding by contour with said connecting zones respectively to connect with a left and a right lateral side of said first induction zone and adhered to said connecting zones.

13. The 3 dimensional touch module as claimed in claim 10, wherein said touch module further comprises a soft circuit board located between said base plate and said induction thin film, and is stuck firm by means of said adhesive layer.

14. The 3 dimensional touch module as claimed in claim 10, wherein said touch module further comprises a printed layer provided on said base surface of said base plate and is located between said base plate and said adhesive layer.

15. The 3 dimensional touch module as claimed in claim 10, wherein said touch module further comprises a printed layer provided on said induction thin film and is located between said induction thin film and said substrate layer.

16. The 3 dimensional touch module as claimed in claim 10, wherein said substrate layer includes a main layer, and at least an engaging member protruding out of said main layer.

17. A manufacturing method of a 3 dimensional touch module comprising:
step A: to provide a planar base plate which includes a touch surface and a base surface respectively on contrary sides;
step B: to stick an induction thin film on said base surface of said base plate by means of an adhesive layer;
step C: to heat said base plate and said induction thin film and to integrally pressing shape said base plate on said induction thin film to form a protruding shape; and
step D: to form a substrate layer on a surface of said induction thin film by a mode of injection shaping.

18. The manufacturing method of a 3 dimensional touch module as claimed in claim 17, wherein said induction thin film is a nanometer carbon tube thin film.

19. The manufacturing method of a 3 dimensional touch module as claimed in claim 17, wherein said method further comprises a step E between said steps A and B, in said step E, a printed layer is formed after drying printing ink on said base surface of said base plate and said surface of said induction thin film.

20. The manufacturing method of a 3 dimensional touch module as claimed in claim 17, wherein said base plate and said induction thin film in said step C have their left and right sides of and/or their front and rear sides protruded in an arched way gradually from said sides to a center area of said base plate and said induction thin film respectively; and a middle area of said base plate is planar or curved.
